(19) United States
(12) Patent Application Publication
(10) Pub. No.: US 2026/0337776 A1
(43) Pub. Date: Oct. 29, 2026

(54) METAL COMPLEX

(71) Applicants: DAIKIN INDUSTRIES, LTD., Osaka (JP); The University of Tokyo, Tokyo (JP)

(72) Inventors: Akiyoshi YAMAUCHI, Osaka (JP); Yosuke Kishikawa, Osaka (JP); Shigehito Sagisaka, Osaka (JP); Hisataka Hayashi, Osaka (JP); Shingo Nakamura, Osaka (JP); Kazunori Horiguchi, Osaka (JP); Naoyuki Hoshiya, Osaka (JP); Yukihiro Shimogaki, Tokyo (JP); Jun Yamaguchi, Tokyo (JP); Takeshi Momose, Tokyo (JP); Noboru Sato, Tokyo (JP)

(73) Assignees: DAIKIN INDUSTRIES, LTD., Osaka (JP); The University of Tokyo, Tokyo (JP)

(21) Appl. No.: 19/547,881

(22) Filed: Feb. 24, 2026

Related U.S. Application Data
(63) Continuation of application No. PCT/JP2024/030046, filed on Aug. 23, 2024.

(30) Foreign Application Priority Data
Aug. 24, 2023 (JP) 2023-136534

(51) Int. Cl. C23C 16/455; C07F 11/00; C07F 15/06; C07F 17/00; C07F 17/02; H10P 14/43

(52) U.S. Cl. CPC C23C 16/45553; C07F 11/00; C07F 15/06; C07F 17/00; C07F 17/02; H10P 14/43

(57) ABSTRACT

A raw material complex for forming a thin metal film, having a central metal and a ligand coordinated to the central metal, wherein the central metal has an atomic polarizability of 45 to 51 and the complex satisfies the following conditions: a polarizability volume≤200 and a relative dielectric constant≤2.20.

### CROSS-REFERENCE TO RELATED APPLICATION

This application is a continuation application of International Application No. PCT/JP2024/030046 filed on Aug. 23, 2024 which claims the benefit of priority from Japanese Patent Application No. 2023-136534 filed on Aug. 24, 2023 and designating the U.S., the entire contents of which are incorporated herein by reference.

### TECHNICAL FIELD

The present disclosure relates to a metal complex.

### BACKGROUND ART

Methods using an atomic layer deposition (hereinafter also referred to as ALD) have been known as methods of film deposition on various substrates, and various metal compounds are used as raw material compounds.

### CITATION LIST

### Patent Literature

### Patent Literature 1

JP 2021-36068 A

### SUMMARY

### [Item 1]

A raw material complex for forming a thin metal film, having a central metal and a ligand coordinated to the central metal,
wherein the central metal has an atomic polarizability of 45 to 51 and the complex satisfies the following conditions:
a polarizability volume≤200 and
a relative dielectric constant≤2.20.

### Advantageous Effects

The complex disclosed herein has a high vapor pressure, allowing for low-temperature vaporization when used as a raw material compound for ALD, as a result of which the complex disclosed herein is inhibited from its decomposition by heat.

### BRIEF DESCRIPTION OF DRAWINGS

FIG. 1 is a schematic view illustrating an example of a film deposition apparatus for carrying out the atomic layer deposition disclosed herein.

FIG. 2 is a graph plotted with the values calculated using the calculation method of the present invention (by Rev. 3) and the values calculated using the existing COSMO-SAC method.

FIG. 3 is a table showing the values calculated using the calculation method of the present invention (by Rev. 3) and the values calculated using the existing COSMO-SAC method.

FIG. 4 is the results of TG-DTA analysis for the compound of Example 1.

FIG. 5 is the results of TG-DTA analysis for the compound of Comparative Example 1.

### DESCRIPTION OF EMBODIMENTS

The present disclosure will be described below. With the proviso that the following description is intended to concretize the technical ideas according to the present disclosure, and the invention is not limited to the following, unless otherwise specified.

### (Complex)

The complex disclosed herein has a central metal and a ligand coordinated to the central metal, wherein (i) the central metal has an atomic polarizability of 45 to 51, and the complex satisfies the following conditions:
a polarizability volume≤200 and
a relative dielectric constant≤2.20 or the complex has a central metal and a ligand coordinated to the central metal, or wherein
(ii) the central metal has an atomic polarizability of 52 to 90, and the complex satisfies the following conditions:
a polarizability volume≤240 and
a relative dielectric constant≤2.50.

In ALD, a raw material compound is typically vaporized in a vaporizer, and the gaseous raw material compound is then introduced into a film deposition chamber, and is deposited on a substrate to form a film of the raw material compound in the film deposition chamber. This film of such a raw material compound is then reduced to form, for example, a metal film. That is, in ALD, a raw material compound is first vaporized, the and generally heated during vaporization. However, an elevated heating temperature can cause decomposition of the complex, resulting in a risk of a decomposition product being contaminated into a film as an impurity.

The complex disclosed herein that satisfies the above conditions has, on the other hand, a high vapor pressure. Therefore, the complex disclosed herein can be vaporized at a relatively low temperature. This results in inhibition of the decomposition of the complex and inhibition of an impurity from being contaminated into a film.

### (i) in the Case of Central Metal Having Atomic Polarizability of 45 to 51

The complex disclosed herein has a polarizability volume of 200 or less, for example, 190 or less, 180 or less, 170 or less, 160 or less, 150 or less, 140 or less, 130 or less, 125 or less, or 120 or less. The lower limit of the polarizability volume of the complex disclosed herein is not limited, and may be, for example, 10 or more, 30 or more, 50 or more, 60 or more, 70 or more, or 80 or more.

The complex disclosed herein has a relative dielectric constant of 2.20 or less, for example, 2.10 or less, 2.00 or less, 1.90 or less, 1.80 or less, 1.70 or less, or 1.60 or less. The lower limit of the relative dielectric constant of the complex disclosed herein is not limited, and may be, for example, 1.10 or more, 1.20 or more, 1.30 or more, 1.40 or more, or 1.50 or more.

In one embodiment, the complex disclosed herein in case (i) may satisfy the following conditions:
a polarizability volume≤180 and a relative dielectric constant≤2.00;
a polarizability volume≤170 and a relative dielectric constant≤1.90;
a polarizability volume≤160 and a relative dielectric constant≤1.80;
a polarizability volume≤125 and a relative dielectric constant≤2.20;
a polarizability volume≤120 and a relative dielectric constant≤2.20; or
a polarizability volume≤120 and a relative dielectric constant≤2.00.

### (ii) in the Case of Central Metal Having Atomic Polarizability of 52 to 90

The complex disclosed herein has a polarizability volume of 240 or less, for example, 234 or less, 230 or less, 220 or less, 210 or less, 200 or less, 190 or less, or 180 or less. The lower limit of the polarizability volume of the complex disclosed herein is not limited, and may be, for example, 10 or more, 30 or more, 50 or more, 60 or more, 70 or more, or 80 or more.

The complex disclosed herein has a relative dielectric constant of 2.50 or less, for example, 2.40 or less, 2.36 or less, 2.30 or less, 2.00 or less, 1.90 or less, 1.80 or less, 1.70 or less, or 1.60 or less. The lower limit of the relative dielectric constant of the complex disclosed herein is not limited, and may be, for example, 1.10 or more, 1.20 or more, 1.30 or more, 1.40 or more, or 1.50 or more.

In one embodiment, the complex disclosed herein in case (ii) may satisfy the following conditions:
a polarizability volume≤220 and a relative dielectric constant≤2.50;
a polarizability volume≤234 and a relative dielectric constant≤2.36;
a polarizability volume≤200 and a relative dielectric constant≤2.40; or
a polarizability volume≤180 and a relative dielectric constant≤2.30.

The complex disclosed herein having a polarizability volume and a relative dielectric constant within the above ranges has a high vapor pressure and can be vaporized at a relatively low temperature.

In one embodiment, the complex has a surface charge density such that an area having a surface charge density of 0.007 e/Å² or more is preferably 10% or less, more preferably 5% or less, and still more preferably 3% or less, with respect to the entire molecular area.

In one embodiment, the complex has a surface charge density such that an area having a surface charge density of −0.007 e/Å² or less is preferably 10% or less, more preferably 5% or less, and still more preferably 3% or less, with respect to the entire molecular area.

In one embodiment, the complex has a surface charge density such that an area having a surface charge density of 0.007 e/Å² or more is preferably 10% or less, more preferably 5% or less, and still more preferably 3% or less, with respect to the entire molecular area, and an area having a surface charge density of −0.007 e/Å² or less is preferably 10% or less, more preferably 5% or less, and still more preferably 3% or less, with respect to the entire molecular area.

Herein, the entire molecular area is a surface area expressed as an aggregate of atoms having the atomic radii used in a COSMO-SAC method which will be described below.

The polarizability volume, relative dielectric constant, surface charge density, and vapor pressure described above can be measured by simulation.

Examples of the above-described simulation include a COSMO-SAC (Conductor-like Screening Model-Segment Activity Coefficient) method, a DET (Density Functional Theory) method, and an AMS (Amsterdam Modeling Suit) method.

The COSMO-SAC method is generally applied to calculate a vapor pressure, whereas it is difficult to accurately predict the vapor pressure of the metal complex involved in the present invention. Therefore, in the present invention, the following procedure has been added to the COSMO-SAC method to improve the accuracy of predicting the vapor pressure of a metal complex. The simulation method with improved vapor pressure prediction accuracy is hereinafter referred to as an “improved COSMO-SAC method.” Details of a method for improving prediction accuracy have been described in “Study on Vapor Pressure Prediction of Metal Complexes by COSMO-SAC Method” (Noboru Sato et al., The Society of Chemical Engineers, Japan, 53rd Autumn Meeting), and the main points of which will be described below.

In calculating a vapor pressure in the present invention, the COSMO-SAC method more specifically uses an empirical parameter (ε_{dsp}) determined for each atomic species upon calculating a molecular activity coefficient γ_{dsp} due to dispersion force. With the proviso that there is a correlation between ε_{dsp} and the polarizability of a metal atom, α_{M}, as represented by the correlation equation:

ε_{dsp}=1035×α_{M}^{1.34}.

Such a correlation equation can be used to predict an unknown ε_{dsp}. The polarizability of a metal atom varies depending on a functional group to which the atom is bonded, so that it is determined for each complex. The polarizability of the ligand is subtracted from the polarizability of the complex molecule to determine the polarizability of the central metal, α_{M} (see, below).

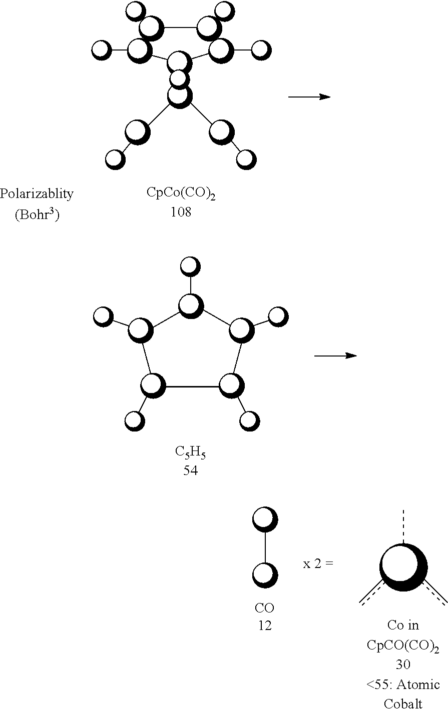

There is a correlation between the polarizability α_{Mol} and γ_{dsp} of a molecule, as represented by the following correlation equation:

$$( - T \cdot ln ( {γ}_{dsp} ) = \frac{50. \times {α}_{Mol}}{1 + 0.02 {α}_{Mol}} )$$

When the value of −T·ln(γ_{dsp}) deviates from the correlation equation described above, the calculated vapor pressure P_{COSMO} is overestimated or underestimated by the difference (AE) compared to the actual value. This error can be corrected by multiplying P_{COSMO} by exp (AE/RT), and a more accurate vapor pressure P_{COSMO}* can be calculated as P_{COSMO}*=P_{COSMO}×exp(ΔE/RT).

The COSMO-SAC method underestimates vapor pressures of complexes containing tertiary carbon, quaternary carbon, and tertiary nitrogen. The cause is considered to be due to overestimation of the dispersion force of a surface of these branched atoms. Then, a surface area of tertiary atoms is converted to ½ thereof and a surface area of quaternary atoms to 0, to calculate a molecular activity coefficient γ_{dsp}*, and the calculated vapor pressure P_{COSMO}* is multiplied by γ_{dsp}*/γ_{dsp} to enable an actual vapor pressure to be reproduced.

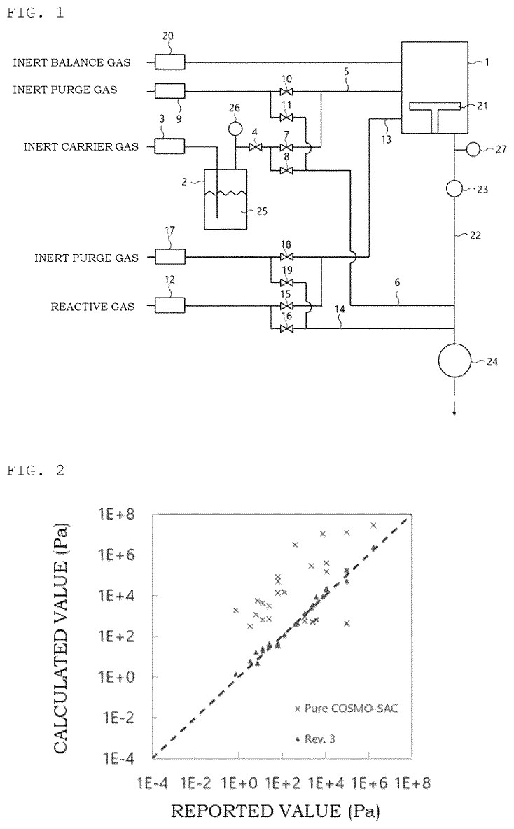

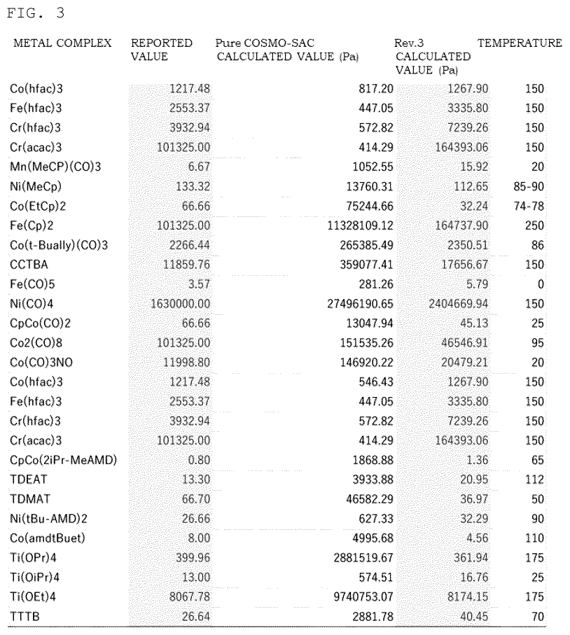

The results of comparison between the predicted and reported vapor pressures of metal complexes are shown in FIG. 2 and FIG. 3. As the predicted values, both of values calculated using the “improved COSMO-SAC method” described above and values calculated using the existing COSMO-SAC method are shown. The calculated values of the present invention predict the vapor pressures with higher accuracy than those calculated using the existing method.

The DFT method is applied to prediction of a polarizability volume, a relative dielectric constant, and a surface charge density, and the polarizability volume is predicted using Gaussian09W and measured at the B3LYP/6-311+G(d, p) level. In predicting the relative dielectric constant, AMS (Amsterdam Modeling Suit) is used to predict the density of a metal complex in a liquid-phase, which is necessary for the prediction of the relative dielectric constant, and the polarizability and the density in a liquid phase are used to predict the relative dielectric constant based on the Clausius-Mossotti relational expression. Moreover, the surface charge density is predicted using AMS (Amsterdam Modeling Suit) and measured at the BP86/TZP level.

The complex disclosed herein is preferably an organometallic compound. The organometallic compound is a metal atom and a ligand coordinated to the metal atom, which is specifically, a monodentate ligand and/or a polydentate ligand.

Examples of the monodentate ligand include halogen, hydride, alkyl, alkenyl, cycloalkyl, aryl, alkynyl, alkylimino, amine, dialkylaminoalkyl, monoalkylamino, dialkylamino, alkoxy, alkoxyalkyl, hydrazide, phosphide, nitrile, silyl, and carbonyl.

Examples of a bidentate ligand that is the polydentate ligand include diamine, di(silyl-alkyl)amino, di(alkyl-silyl)amino, disilylamino, dialkylaminoalkoxy, alkoxyalkyldialkylamino, siloxy, diketonate, cyclopentadienyl, pyrazolate, ketoiminate and diketiminate.

Examples of a tridentate or higher ligand that is the polydentate ligand include amidinate, guanidinate, phosphaguanidinate, and phosphaamidinate.

The above-described ligand has an atom coordinating to a metal in the ligand, which the atom has a Pauling electronegativity of 3.1 or less, and the ligand may be a monodentate, bidentate, or tridentate ligand.

In some embodiments, the ligand is preferably carbonyl, alkyne, alkylamine, or hydride, as a monodentate ligand.

In some embodiments, the ligand is preferably alkyldiene, cyclopentadiene, or acetylacetonate, as a bidentate ligand.

In some embodiments, the ligand is preferably amidinate, as a tridentate ligand.

### (i) in the Case of Central Metal Having Atomic Polarizability of 45 to 51

The central metal of the complex disclosed herein may preferably be cobalt, nickel, or copper and more preferably cobalt.

### (ii) in the Case of Central Metal Having Atomic Polarizability of 52 to 90

The central metal of the complex disclosed herein may preferably be molybdenum, ruthenium, or tungsten and more preferably ruthenium or tungsten.

Having the above-described central metal may allow the complex of the present disclosure to have a higher vapor pressure.

### (i) in the Case of Central Metal Having Atomic Polarizability of 45 to 51

The vapor pressure of the complex disclosed herein at 100° C. may preferably be 1.0 Torr or higher, more preferably 2.0 Torr or higher, and still more preferably 3.0 Torr or higher, and it may be, for example, 3.5 Torr or higher, 4.5 Torr or higher, 5.5 Torr or higher, 6.0 Torr or higher, 6.3 Torr or higher, or 6.7 Torr or higher. The upper limit of the vapor pressure of the complex disclosed herein at 100° C. is not limited, and may be, for example, 55 Torr or less, 50 Torr or less, 45 Torr or less, 40 Torr or less, 35 Torr or less, 30 Torr or less, 25 Torr or less, 20 Torr or less, 15 Torr or less, 10 Torr or less, 8 Torr or less, 7 Torr or less, or 6 Torr or less.

In a preferred embodiment,
the central metal is cobalt and the complex has a vapor pressure at 100° C. of 6.0 Torr or more;
the central metal is nickel and the complex has a vapor pressure at 100° C. of 6.3 Torr or more; or
the central metal is copper and the complex has a vapor pressure at 100° C. of 6.7 Torr or more.

### (ii) in the Case of Central Metal Having Atomic Polarizability of 52 to 90

The vapor pressure of the complex disclosed herein at 100° C. is preferably 0.6 Torr or more, more preferably 1.0 Torr or more, still more preferably 2.0 Torr or more, and even still more preferably 2.8 Torr or more, and it may be for example 3.0 Torr or more, 3.5 Torr or more, 3.6 Torr or more, 4.5 Torr or more, or 5.5 Torr or more. The upper limit of the vapor pressure of the complex disclosed herein at 100° C. is not limited, and may be, for example, 10 Torr or less, 8 Torr or less, 7 Torr or less, or 6 Torr or less.

In a preferred embodiment,
the central metal is molybdenum, and the complex has a vapor pressure at 100° C. of 0.6 Torr or more;
the central metal is ruthenium, and the complex has a vapor pressure at 100° C. of 2.8 Torr or more; or
the central metal is tungsten, and the complex has a vapor pressure at 100° C. of 3.6 Torr or more.

The vapor pressures staying within the above ranges allow for vaporization of the complex at low temperatures and inhibit decomposition of the complex. This ultimately inhibits an impurity from being contaminated into a film in ALD using the complex disclosed herein as a raw material.

The vapor pressure of the complex disclosed herein can be measured by introducing the complex into a bottle equipped with a pressure system and measuring it at each specified temperature.

When the ligand of the complex disclosed herein contains an alkyl group having three or more carbon atoms, the alkyl group may preferably have branched carbon. In other words, the complex disclosed herein may have at least one branched alkyl group having three or more carbon atoms.

Examples of the complex disclosed herein include the following complexes:

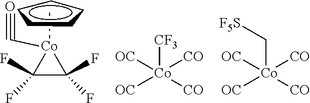

The complex disclosed herein can be used in a variety of applications, including, for example, an atomic layer deposition, a chemical vapor deposition, catalytic applications (for example, a catalyst for hydrogen fuel cells and a catalyst for hydrogen generation reactions), a cathode electrode for lithium ion batteries, a battery anode, a photodetector, a biosensing, a high-performance thermoelectric material, and a catalyst.

Currently, in semiconductor manufacturing processes, many chemical vapor deposition growth methods (CVD) and atomic layer deposition (ALD) processes using metal complexes have been utilized.

The film types thereof are widely ranged, including, in addition to metal films, a metal nitride, a metal oxide, and a metal carbide, which have been widely investigated in the following processes:
High relative dielectric constant gate insulating films: HfOx, HfLaOx, and the like.
Gate cap films: TiAlOx and the like.
Capacitor insulating films (for DRAM): Zrox, AlOx, HfOx, and the like.
Block oxide films (for flash memories): AlOx and the like.
Metal gate electrodes (including a work function metal): W, TiN, TaN, TiAlC, TiAlN, and the like.
Wiring materials (including a barrier metal, a liner metal, a seed metal, and a metal cap): Cu, Co, Ru, Mo, TaN, TiN, MON, WC, and the like.
Buried materials for via holes and contact holes (including an adhesion layer): W, Mo, Co, Ru, TiN, MON, WC, and the like.
Metal hard masks (including a sidewall spacer): TiN, TiOx, and the like.
Etching stop layers: AlO, AlNO, and the like.
Materials for promoting selective growth of metal films (wiring materials and buried materials): Pd and the like.
Highly thermal conductive insulating films: AlN and the like.

Furthermore, even in an atomic layer etching (ALE) process, a metal complex may be used to etch a difficult-to-etch material such as a high relative dielectric constant insulating film.

### (Atomic Layer Deposition)

The present disclosure provides an atomic layer deposition using the above-described complexes of the present disclosure as raw material compounds.

The complex disclosed herein has a high vapor pressure and therefore can be vaporized at a relatively low temperature, for example, 200° C. or lower. Accordingly, vaporization at low temperatures inhibits the complex, which is a raw material compound from being decomposed, and inhibits an impurity from being contaminated into a thin film to be formed.

The atomic layer deposition disclosed herein is carried out, for example, using a film deposition apparatus such as the apparatus shown in FIG. 1. In a film deposition chamber 1, the raw material compound vaporized in a raw material container 2 undergoes deposition processing in which it is deposited on a substrate preliminarily prepared, then to deposit the raw material compound on the substrate. Thereafter, in the film deposition chamber 1, the deposit undergoes film deposition processing such that a thin film is deposited by reduction with reducing gas, then to form the thin film. It is to be noted that FIG. 1 shows only one raw material container 2, however, it may be two or more, for example, when two or more raw material compounds are used. The film deposition apparatus will be specifically described below.

In the raw material container 2, a raw material liquid containing a raw material compound is heated and vaporized, if necessary. The vaporized raw material compound is transported to the film deposition chamber 1 by inert carrier gas. In order to vaporize the raw material liquid, the raw material container 2 may have been heated to, for example, 30° C. or higher, 45° C. or higher, 200° C. or lower, or 120° C. or lower. The raw material compound may have alternatively been heated to 45° C. to 120° C. or 30° C. to 200° C.

The inert carrier gas described above is, for example, nitrogen, argon, helium. The inert carrier gas is regulated for its flow rate using a mass flow controller (hereinafter also referred to as “MFC”) 3. The pressure inside the raw material container 2 is adjusted using a needle valve 4. The flow rate of the inert carrier gas is, for example, 10 sccm to 100 sccm. The pressure inside the raw material container 2 is measured using a pressure gauge 26. The pressure value is, for example, 10 Torr to 100 Torr.

The raw material container 2 is connected to a line that branches into a supply line 5 leading to the film deposition chamber 1 and an exhaust line 6. The supply line and exhaust line 6 have a valve 7 and a valve 8, respectively, which are opened and closed to switch between supply and exhaust of a raw material. The supply line 5 and exhaust line 6 may have a heating mechanism. Examples of the heating mechanism include a heater disposed around piping, typically a jacket heater.

The supply line 5 and exhaust line 6 can be purged with inert purge gas. Examples of the inert purge gas include nitrogen, argon, helium. The inert purge gas is regulated for its flow rate by an MFC 9. The flow rate of the inert purge gas is, for example, 10 sccm to 100 sccm. The purge destination is switched to the supply line 5 or the exhaust line 6 by opening and closing the valve 10 and the valve 11, respectively. A sequence is set such that when a raw material compound flows through the supply line 5, the inert purge gas flows through the exhaust line 6, and when the raw material compound flows through the exhaust line 6, the inert purge gas flows through the supply line 5.

When reactant gas is high-pressure gas such as hydrogen or oxygen, it is supplied with regulation on its flow rate using a MFC 12. The flow rate is, for example, 10 sccm to 1,000 sccm. When the reactant gas is liquid at normal temperature and pressure, such as water or formic acid, it is supplied using the inert carrier gas, as with the raw material compound.

A supply line for the reactant gas branches into a supply line 13 which leads to the film deposition chamber 1, and an exhaust line 14. The supply line 13 and exhaust line 14 have a valve 15 and a valve 16, respectively, and supply of the reducing gas and exhaust thereof are switched by opening and closing the valve 15 and the valve 16, The supply line 13 and exhaust line 14 may respectively. Examples of the heating mechanism have a heating mechanism include a heater disposed around piping, typically a jacket heater.

The supply line 13 and exhaust line 14 can be purged with the inert purge gas. Examples of the inert purge gas include nitrogen, argon, helium. The flow rate of the inert purge gas is adjusted by the MFC 17. The flow rate of the inert purge gas is, for example, 10 sccm to 100 sccm. The purge destination is switched to the supply line 13 or the exhaust line 14 by opening and closing a valve 18 and a valve 19, respectively. A sequence is set so that when the reactant gas flows through the supply line 13, the inert purge gas flows into the exhaust line 14, and when the reactant gas flows through the exhaust line 14, the inert purge gas flows into the supply line 13.

An inert balance gas line for adjusting a flow rate may be connected to the film deposition chamber 1. Examples of the inert balance gas include nitrogen, argon, helium. The inert balance gas is regulated for its flow rate using an MFC 20. The flow rate of the inert balance gas is, for example, 10 sccm to 100 sccm.

The film deposition chamber 1 is equipped with a film deposition stage 21. Before introduced with raw material compounds, the film deposition stage 21 typically contact the second main surface of a substrate on which a film is to be deposited. The second main surface of the substrate is the surface of the opposite side of the first main surface.

In the film deposition chamber 1, the raw material compound vaporized in the raw material container 2 is introduced. That is, the vaporized raw material compound comes into contact with the first main surface of the above-described substrate, and undergo film deposition processing such that the vaporized raw material compound is deposited on the substrate.

In the film deposition chamber 1, following the deposition processing, the deposit is reacted with the reactant gas to undergo film deposition processing such that the deposit forms a thin film.

The film deposition chamber 1 may be equipped with a heating mechanism, and it is, for example, heated to 100° C. to 300° C.

The film deposition chamber 1 has a discharge line 22 for discharging gas. The discharge line 22 discharges the raw material compound, carrier gas, reducing gas, and the like, which remain in the film deposition chamber 1. Examples of the method for discharging them include a method for purging the system with inert gas such as nitrogen or argon, a method for discharging them by reducing the pressure inside the system, or a combination of these methods.

The discharge line 22 is equipped with a butterfly valve 23 for adjusting a pressure in the film deposition chamber 1. The film deposition chamber 1 is regulated for its pressure by the opening of the butterfly valve 23, and the pressure in the film deposition chamber 1 is, for example, Torr to 30 Torr.

The discharge line 22 is connected to the exhaust line 6 and the exhaust line 14 downstream of the butterfly valve 23 (i.e., in the opposite direction to the film deposition chamber 1). The discharge line 22 has a pump 24 downstream of a connection point with the exhaust line 6 and the exhaust line 14.

As described above, the raw material liquid 25 containing the raw material compound is present in the raw material container 2, and the raw material compound vaporized in the raw material container 2 is transported by the carrier gas through the supply line 5 to the film deposition chamber 1. In the film deposition chamber 1, the raw material compound vaporized in the raw material container 2 is deposited on a substrate preliminarily prepared. Thereafter, the deposit is reacted with the reactant gas to form a thin film in the film deposition chamber 1. This procedure is repeated a specified number of times to obtain a thin film of the desired thickness.

Before introduced with the raw material compound, the above-described substrate is typically disposed on a film deposition stage installed in the film deposition chamber 1.

The material constituting the above-described substrate is not limited, and examples thereof include metals such as copper, silver, gold, platinum, nickel, palladium, and aluminum; silicon; ceramics such as indium arsenide, indium gallium arsenide, silicon oxide, silicon nitride, silicon carbide, titanium nitride, tantalum oxide, tantalum nitride, titanium oxide, titanium nitride, ruthenium oxide, zirconium oxide, hafnium oxide, lanthanum oxide, and gallium nitride; and glass.

In one embodiment, the material constituting the above-described substrate is copper, silver, gold, platinum, nickel, palladium, or aluminum, preferably copper.

The shape of the above-described substrate is not limited, and may be, for example, platy, rod-like, spherical, layer-like, fibrous, flaky.

In one embodiment, the shape of the substrate may be a layer provided on a substrate, such as wiring on a wiring board.

A temperature of a substrate upon depositing the raw material compound on the substrate may be, for example, 20 to 300° C., preferably 50 to 200° C., more preferably 80 to 180° C., and still more preferably 100 to 160° C.

According to the atomic layer deposition of the present disclosure, a thin film that is contaminated with less amount of impurity can be deposited. Therefore, the atomic layer deposition of the present disclosure can be suitably used, for example, in manufacturing of semiconductor substrates.

### (Method for Selecting Raw Material Complex for Use in Atomic Layer Deposition)

The present disclosure provides a method for selecting a raw material complex for use in an atomic layer deposition, comprising selecting the raw material complex which has
(i) a central metal having an atomic polarizability of 45 to 51,
   a polarizability volume of 200 or less,
   a relative dielectric constant of 2.20 or less, and
   a surface charge density such that an area having a surface charge density of 0.007 e/Å² or more is 10% or less with respect to an entire molecular area, or an area having a surface charge density of −0.007 e/Å² or less is 10% or less with respect to an entire molecular area, or
   the raw material complex which has
(ii) a central metal having an atomic polarizability of 52 to 90,
   a polarizability volume of 220 or less,
   a relative dielectric constant of 2.50 or less, and
   a surface charge density such that an area having a surface charge density of 0.007 e/Å² or more is 10% or less with respect to an entire molecular area, or an area having a surface charge density of −0.007 e/Å² or less is 10% or less with respect to an entire molecular area.

According to the method for selecting a complex disclosed herein, a complex having a high vapor pressure can be found.

### (i) in the Case of Central Metal Having Atomic Polarizability of 45 to 51

In the method for selecting a complex disclosed herein, the complex having a polarizability volume of 200 or less, for example, 190 or less, 180 or less, 170 or less, 160 or less, 150 or less, 140 or less, 130 or less, 125 or less, or 120 or less, is selected. Also, the complex having a polarizability volume of, for example, 10 or more, 30 or more, 50 or more, 60 or more, 70 or more, or 80 or more, is selected.

In the method for selecting a complex disclosed herein, the complex having a relative dielectric constant of 2.20 or less, for example, 2.10 or less, 2.00 or less, 1.90 or less, 1.80 or less, 1.70 or less, or 1.60 or less, is selected. Also, the complex having a relative dielectric constant of, for example, 1.10 or more, 1.20 or more, 1.30 or more, 1.40 or more, or 1.50 or more, is selected.

### (ii) In the Case of Central Metal Having Atomic Polarizability of 52 to 90

In the method for selecting a complex disclosed herein, the complex having a polarizability volume of 240 or less, for example, 234 or less, 230 or less, 220 or less, 210 or less, 200 or less, 190 or less, or 180 or less, is selected. Also, the complex having a polarizability volume of, for example, 10 or more, 30 or more, 50 or more, 60 or more, 70 or more, or 80 or more, is selected.

In the method for selecting a complex disclosed herein, the complex having a relative dielectric constant of 2.50 or less, for example, 2.40 or less, 2.36 or less, 2.30 or less, 2.00 or less, 1.90 or less, 1.80 or less, 1.70 or less, or 1.60 or less, is selected. Also, the complex having a relative dielectric constant of, for example, 1.10 or more, 1.20 or more, 1.30 or more, 1.40 or more, or 1.50 or more, is selected.

In the method for selecting a complex disclosed herein, a complex having a surface charge density such that an area having a surface charge density of 0.007 e/Å² or more is 10% or less with respect to the entire molecular area, or a complex having a surface charge density such that an area having a surface charge density of −0.007 e/Å² or less is 10% or less with respect to the entire molecular area, is selected.

In one embodiment, the complex has a surface charge density such that an area having a surface charge density of 0.007 e/Å² or more is preferably 10% or less, more preferably 5% or less, and still more preferably 3% or less, with respect to the entire molecular area.

In one embodiment, the complex has a surface charge density such that an area having a surface charge density of −0.007 e/Å² or less is preferably 10% or less, more preferably 5% or less, and still more preferably 3% or less, with respect to the entire molecular area.

In one embodiment, the complex has a surface charge density such that an area of having a surface charge density 0.007 e/Å² or more is preferably 10% or less, more preferably 5% or less, and still more preferably 3% or less, with respect to the entire molecular area, and the area having a surface charge density of −0.007 e/Å² or less is preferably 10% or less, more preferably 5% or less, and still more preferably 3% or less, with respect to the entire molecular area.

### (i) in the Case of Central Metal Having Atomic Polarizability of 45 to 51

In the method for selecting a complex disclosed herein, the complex having a vapor pressure at 100° C. of preferably 1.0 Torr or more, more preferably 2.0 Torr or more, and still more preferably 3.0 Torr or more, for example, 3.5 or 4.5 Torr or more, 5.5 Torr or more, 6.0 Torr or more, 6.3 Torr or more, or 6.7 Torr or more, is selected. Also, the complex having a vapor pressure at 100° C. of, for example, 55 Torr or less, 50 Torr or less, 45 Torr or less, 40 Torr or less, 35 Torr or less, 30 Torr or less, 25 Torr or less, 20 Torr or less, 15 Torr or less, 10 Torr or less, 8 Torr or less, 7 Torr or less, or 6 Torr or less, is selected.

### (ii) in the Case of Central Complex Having Atomic Polarizability of 52 to 90

In the method for selecting a complex disclosed herein, the complex having a vapor pressure at 100° C. of preferably 0.6 Torr or more, more preferably 1.0 Torr or more, still more preferably 2.0 Torr or more, and even still more preferably 2.8 Torr or more, for example, 3.0 Torr or more, 3.5 Torr or more, 3.6 Torr or more, 4.5 Torr or more, or 5.5 Torr or more, is selected. Also the complex having a vapor pressure at 100° C. of, for example, 10 Torr or less, 8 Torr or less, 7 Torr or less, or 6 Torr or less, is selected.

The complex having a polarizability volume, a relative dielectric constant, a surface charge density, and a vapor pressure within the above ranges has a high vapor pressure and can be vaporized at a relatively low temperature.

In one embodiment of the method for selecting a complex disclosed herein:

### (i) in the Case of Central Metal Having Atomic Polarizability of 45 to 51

The complex that satisfies the following conditions is selected:
a polarizability volume≤180 and a relative dielectric constant≤2.00;
a polarizability volume≤170 and a relative dielectric constant≤1.90;
a polarizability volume≤160 and a relative dielectric constant≤1.80;
a polarizability volume≤125 and a relative dielectric constant≤2.20;
a polarizability volume≤120 and a relative dielectric constant≤2.20; or
a polarizability volume≤120 and a relative dielectric constant≤2.00.

In one embodiment of the method for selecting a complex disclosed herein:

### (ii) in the Case of Central Metal Having Atomic Polarizability of 52 to 90

The complex that satisfies the following conditions is selected:
a polarizability volume≤220 and a relative dielectric constant≤2.50;
a polarizability volume≤234 and a relative dielectric constant≤2.36;
a polarizability volume≤200 and a relative dielectric constant≤2.40; or
a polarizability volume≤180 and a relative dielectric constant≤2.30.

The polarizability volume and relative dielectric constant described above can be determined by simulation.

Examples of the above-described simulation include a COSMO-SAC (Conductor-like Screening Model-Segment Activity Coefficient) method or a DFT (Density Functional Theory) method. The COSMO-SAC method and the DFT method have the same meanings as above.

In the method for selecting a complex as disclosed herein, the complex whose central metal is preferably cobalt, ruthenium, tungsten, copper, palladium, or molybdenum, more preferably cobalt, ruthenium, tungsten, palladium, or molybdenum, still more preferably cobalt, ruthenium, or tungsten, and particularly preferably cobalt, is selected. In a preferred embodiment, cobalt, nickel, or copper is selected as a central metal having an atomic polarizability of 45 to 51. In another preferred embodiment, molybdenum, ruthenium, or tungsten is selected as a central metal having an atomic polarizability of 52 to 90. The complexes having such central metals may have a higher vapor pressure.

### EXAMPLES

The present disclosure will be described below by way of Examples, but the present disclosure is not limited to the following Examples.

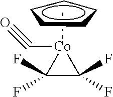

### Example 1

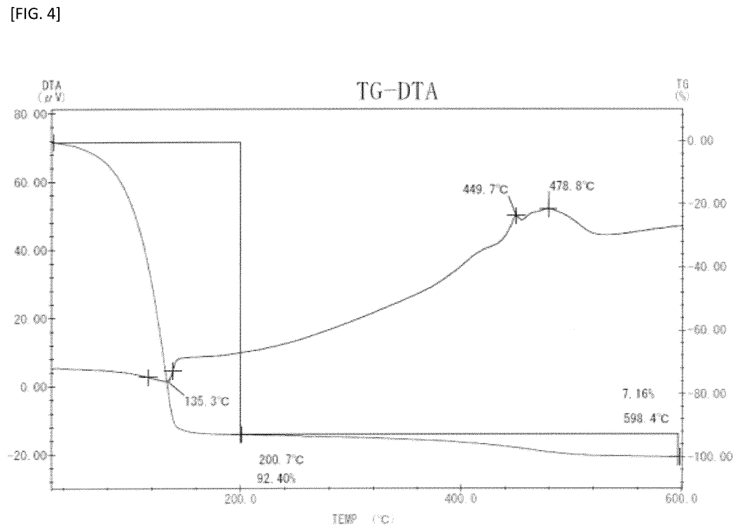

In a glove box, an autoclave with a 30 mL glass inner tube was charged with CpCo(CO)2 (300 mg), NaI (49.35 mg), and dry THF (15 mL), and following gentle stirring, a septum cap was attached. The autoclave was then transferred from the glove box to a draft chamber and trifluoromethyltrimethylsilane (600 mg) was slowly added dropwise with a syringe into the autoclave. The autoclave was closed with a lid and placed in an oil bath, and the contents were heated and stirred at a bath temperature of 65° C. After 2 hours, the heating was stopped. The reaction liquid left to be cooled was concentrated under reduced pressure, and to the resulting residue was added dry hexane (12 mL). The insoluble was removed by filtration through Celite, and the filtrate was concentrated under reduced pressure, yielding 150 mg of a viscous brown liquid (yield: 36%). The results of IR analysis and NMR analysis were compared with those of literature values to confirm that the product obtained was the target compound, and was then analyzed by TG-DTA. The results are shown in FIG. 4.

The level of a vapor pressure of a compound correlates with a Td50 temperature in TG-DTA, and a complex with a low Td50 temperature can be said to have a high vapor pressure.

For the above-described complex, the polarizability volume, relative dielectric constant, and surface charge density of the complex were calculated using the DFT method, and the vapor pressure of the complex was calculated using an improved COSMO-SAC method.

TABLE 1

| | |
|---|---|
| Polarizability volume | |
| Relative dielectric constant | |
| Surface charge density | The area having a surface |
| | charge density of 0.007 e/Å² |
| | or more is 0% with respect to |
| | the entire molecular area. |
| | The area having a surface |
| | charge density of 0.007 e/Å² |
| | or less is 14% with respect |
| | to the entire molecular area. |
| Vapor pressure at 100 °C | 65 Torr |
| Td50 | 150 °C or less |

The vapor pressure of the above-described complex at 100° C. was actually measured and found to be 153 Torr. The comparison of the experimental value and the calculated value confirmed that the values fell within the range of the 99% confidence interval in Rev. 3 in FIG. 2.

### Example 2

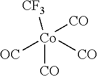

For the above-described complex, the polarizability volume, relative dielectric constant, and surface charge density of the complex were calculated using the DFT method, and the vapor pressure of the complex was calculated using an improved COSMO-SAC method.

TABLE 2

| | |
|---|---|
| Polarizability volume | 99.26 |
| Relative dielectric constant | 1.96 |
| Surface charge density | The area having a surface |
| | charge density of 0.007 e/Å² |
| | or more is 0% with respect to |
| | the entire molecular area. |
| | The area having a surface |
| | charge density of 0.007 e/Å² |
| | or less is 5% with respect to |
| | the entire molecular area. |
| Vapor pressure at 100 °C | 138 Torr |

### Example 3

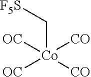

For the above-described complex, the polarizability volume, relative dielectric constant, and surface charge density of the complex were calculated using the DFT method, and the vapor pressure of the complex was calculated using an improved COSMO-SAC method.

TABLE 3

| | |
|---|---|
| Polarizability volume | 125.07 |
| Relative dielectric constant | 1.97 |
| Surface charge density | The area having a surface |
| | charge density of 0.007 e/Å² |
| | or more is 0% with respect |
| | to the entire molecular area. |
| | The area having a surface |
| | charge density of 0.007 e/Å² |
| | or less is 8% with respect to |
| | the entire molecular area. |
| Vapor pressure at 100 °C | 65 Torr |

### Example 4

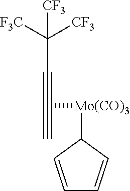

For the above-described complex, the polarizability volume, relative dielectric constant, and surface charge density of the complex were calculated using the DFT method, and the vapor pressure of the complex was calculated using an improved COSMO-SAC method.

TABLE 4

| | |
|---|---|
| Polarizability volume | 195.3 |
| Relative dielectric constant | 2.04 |
| Surface charge density | The area having a surface |
| | charge density of 0.007 e/Å² |
| | or more is 0.1% with respect |
| | to the entire molecular area. |
| | The area having a surface |
| | charge density of 0.007 e/Å² |
| | or less is 10% with respect |
| | to the entire molecular area. |
| Vapor pressure at 100 °C | 5.5 Torr |

### Example 5

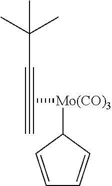

For the above-described complex, the polarizability volume, relative dielectric constant, and surface charge density of the complex were calculated using the DFT method, and the vapor pressure of the complex was calculated using an improved COSMO-SAC method.

TABLE 5

| | |
|---|---|
| Polarizability volume | 194.33 |
| Relative dielectric constant | 2.36 |
| Surface charge density | The area having a surface |
| | charge density of 0.007 e/Å² |
| | or more is 7.0% with respect |
| | to the entire molecular area. |
| | The area having a surface |
| | charge density of 0.007 e/Å² or |
| | less is 9.0% with respect |
| | to the entire molecular area. |
| Vapor pressure at 100 °C | 3.0 Torr |

### Example 6

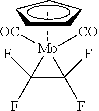

For the above-described complex, the polarizability volume, relative dielectric constant, and surface charge density of the complex were calculated using the DFT method, and the vapor pressure of the complex was calculated using an improved COSMO-SAC method.

TABLE 6

| | |
|---|---|
| Polarizability volume | 148.60 |
| Relative dielectric constant | 2.17 |
| Surface charge density | The area having a surface |
| | charge density of 0.007 e/Å² |
| | or more is 0% with respect to |
| | the entire molecular area. |
| | The area having a surface |
| | charge density of 0.007 e/Å² |
| | or less is 13% with respect |
| | to the entire molecular area. |
| Vapor pressure at 100 °C | 1.3 Torr |

### Example 7

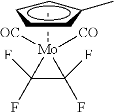

For the above-described complex, the polarizability volume, relative dielectric constant, and surface charge density of the complex were calculated using the DFT method, and the vapor pressure of the complex was calculated using an improved COSMO-SAC method.

TABLE 7

| | |
|---|---|
| Polarizability volume | 162.00 |
| Relative dielectric constant | 2.18 |
| Surface charge density | The area having a surface |
| | charge density of 0.007 e/Å² |
| | or more is 0% with respect to |
| | the entire molecular area. |
| | The area having a surface |
| | charge density of 0.007 e/Å² |
| | or less is 11% with respect to |
| | the entire molecular area. |
| Vapor pressure at 100 °C | 0.61 Torr |

### Example 8

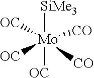

For the above-described complex, the polarizability volume, relative dielectric constant, and surface charge density of the complex were calculated using the DFT method, and the vapor pressure of the complex was calculated using an improved COSMO-SAC method.

TABLE 8

| | |
|---|---|
| Polarizability volume | 234.60 |
| Relative dielectric constant | 2.44 |
| Surface charge density | The area having a surface |
| | charge density of 0.007 e/Å² |
| | or more is 0% with respect to |
| | the entire molecular area. |
| | The area having a surface |
| | charge density of 0.007 e/Å² |
| | or less is 3% with respect to |
| | the entire molecular area. |
| Vapor pressure at 100 °C | 0.73 Torr |

### Example 9

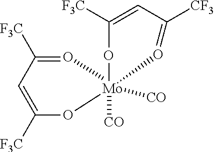

For the above-described complex, the polarizability volume, relative dielectric constant, and surface charge density of the complex were calculated using the DFT method, and the vapor pressure of the complex was calculated using an improved COSMO-SAC method.

TABLE 9

| | |
|---|---|
| Polarizability volume | 234.16 |
| Relative dielectric constant | 2.06 |
| Surface charge density | The area having a surface |
| | charge density of 0.007 e/Å² |
| | or more is 0.2% with respect to |
| | the entire molecular area. |
| | The area having a surface |
| | charge density of 0.007 e/Å² |
| | or less is 7% with respect to |
| | the entire molecular area. |
| Vapor pressure at 100 °C | 2.1 Torr |

### Comparative Example 1

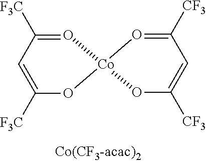

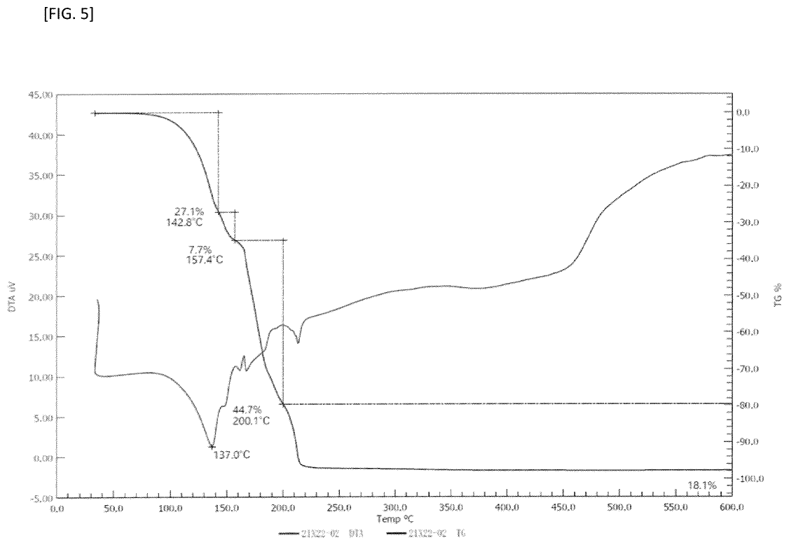

The above-described complex underwent a TG-DTA analysis. The results are shown in FIG. 5.

For the above-described complex, the polarizability volume, relative dielectric constant, and surface charge density of the complex were calculated using the DFT method, and the vapor pressure of the complex was calculated using an improved COSMO-SAC method.

TABLE 10

| Polarizability volume | 245.00 | |
|---|---|---|
| Relative dielectric constant | 1.87 | |
| Surface charge density | The area having a surface | |
| | charge density of 0.007 e/Å² | |
| | or more is 4% with respect to | |
| | the entire molecular area. | |
| | The area having a surface | |
| | charge density of 0.007 e/Å² or | |
| | less is 9% with respect to | |
| | the entire molecular area. | |
| Vapor pressure at 150 °C | 9 | Torr |
| Vapor pressure at 100 °C | 5.5 | Torr |
| Td50 | 175 1 | °C |

### Comparative Example 2

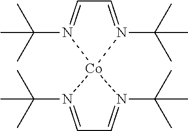

The above-described complex underwent a TG-DTA analysis.

For the above-described complex, the polarizability volume, relative dielectric constant, and surface charge density of the complex were calculated using the DFT method, and the vapor pressure of the complex was calculated using an improved COSMO-SAC method.

TABLE 11

| Polarizability volume | 364.00 | |
|---|---|---|
| Relative dielectric constant | 2.61 | |
| Surface charge density | The area having a surface | |
| | charge density of 0.007 e/Å² | |
| | or more is 4% with respect to | |
| | the entire molecular area. | |
| | The area having a surface | |
| | charge density of 0.007 e/Å² | |
| | or less is 1% with respect to | |
| | the entire molecular area. | |
| Vapor pressure at 110 °C | 0.1 | Torr |
| Td50 | 275 | °C |

### Comparative Example 3

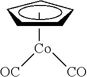

For the above-described complex, the polarizability volume, relative dielectric constant, and surface charge density of the complex were calculated using the DFT method, and the vapor pressure of the complex was calculated using an improved COSMO-SAC method.

TABLE 12

| | |
|---|---|
| Polarizability volume | 107.7 |
| Relative dielectric constant | 2.31 |
| Surface charge density | The area having a surface |
| | charge density of 0.007 e/Å² |
| | or more is 4% with respect to |
| | the entire molecular area. |
| | The area having a surface |
| | charge density of 0.007 e/Å² |
| | or less is 14% with respect to |
| | the entire molecular area. |
| Vapor pressure at 25 °C | 0.34 Torr |

### Comparative Example 4

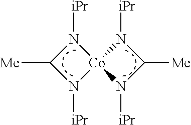

For the above-described complex, the polarizability volume, relative dielectric constant, and surface charge density of the complex were calculated using the DFT method, and the vapor pressure of the complex was calculated using an improved COSMO-SAC method.

TABLE 13

| | |
|---|---|
| Polarizability volume | 259.0 |
| Relative dielectric constant | 2.18 |
| Surface charge density | The area having a surface |
| | charge density of 0.007 e/Å² |
| | or more is 4% with respect to |
| | the entire molecular area. |
| | The area having a surface |
| | charge density of 0.007 e/Å² |
| | or less is 0.5% with respect to |
| | the entire molecular area. |
| Vapor pressure at 100 °C | 1.2 Torr |

### Comparative Example 5

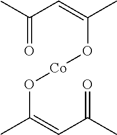

For the above-described complex, the polarizability volume, relative dielectric constant, and surface charge density of the complex were calculated using the DFT method, and the vapor pressure of the complex was calculated using an improved COSMO-SAC method.

TABLE 14

| | |
|---|---|
| Polarizability volume | 174.4 |
| Relative dielectric constant | 2.31 |
| Surface charge density | The area having a surface |
| | charge density of 0.007 e/Å² |
| | or more is 13% with respect to |
| | the entire molecular area. |
| | The area having a surface |
| | charge density of 0.007 e/Å² |
| | or less is 9% with respect to |
| | the entire molecular area. |
| Vapor pressure at 150 °C | 4.7 Torr |

### Comparative Example 6

### Ni(tBu-AMD)2

For the above-described complex, the polarizability volume, relative dielectric constant, and surface charge density of the complex were calculated using the DFT method, and the vapor pressure of the complex was calculated using an improved COSMO-SAC method.

TABLE 15

| | |
|---|---|
| Polarizability volume | 303.7 |
| Relative dielectric constant | 2.2 |
| Surface charge density | The area having a surface |
| | charge density of 0.007 e/Å² |
| | or more is 3% with respect to |
| | the entire molecular area. |
| | The area having a surface |
| | charge density of 0.007 e/Å² |
| | or less is 2% with respect to |
| | the entire molecular area. |
| Vapor pressure at 90 °C | 0.004 Torr |

### Comparative Example 7

### Cu(iPr-AMD)2

For the above-described complex, the polarizability volume, relative dielectric constant, and surface charge density of the complex were calculated using the DFT method, and the vapor pressure of the complex was calculated using an improved COSMO-SAC method.

TABLE 16

| | |
|---|---|
| Polarizability volume | 275.4 |
| Relative dielectric constant | 2.3 |
| Surface charge density | The area having a surface |
| | charge density of 0.007 e/Å² |
| | or more is 7.1% with respect |
| | to the entire molecular area. |
| | The area having a surface |
| | charge density of 0.007 e/Å² |
| | or less is 1.7% with respect |
| | to the entire molecular area. |
| Vapor pressure at 100 °C | 0.04 Torr |

### Comparative Example 8

### Mo(hfac)3

For the above-described complex, the polarizability volume, relative dielectric constant, and surface charge density of the complex were calculated using the DFT method, and the vapor pressure of the complex was calculated using an improved COSMO-SAC method.

TABLE 17

| | |
|---|---|
| Polarizability volume | 293.60 |
| Relative dielectric constant | 2.70 |
| Surface charge density | The area having a surface |
| | charge density of 0.007 e/Å² |
| | or more is 12.0% with respect to |
| | the entire molecular area. |
| | The area having a surface |
| | charge density of 0.007 e/Å² or |
| | less is 8.0% with respect to the |
| | entire molecular area. |
| Vapor pressure at 100 °C | 0.003 Torr |

### Comparative Example 9

### Mo(Me-AMD)3

For the above-described complex, the polarizability volume, relative dielectric constant, and surface charge density of the complex were calculated using the DFT method, and the vapor pressure of the complex was calculated using an improved COSMO-SAC method.

TABLE 18

| | |
|---|---|
| Polarizability volume | 241.04 |
| Relative dielectric constant | 2.29 |
| Surface charge density | The area having a surface |
| | charge density of 0.007 e/Å² |
| | or more is 7.0% with respect |
| | to the entire molecular area. |
| | The area having a surface |
| | charge density of 0.007 e/Å² |
| | or less is 7.0% with respect |
| | to the entire molecular area. |
| Vapor pressure at 100 °C | 0.01 Torr |

### Comparative Example 10

### Mo(iPr-AMD)3

For the above-described complex, the polarizability volume, relative dielectric constant, and surface charge density of the complex were calculated using the DFT method, and the vapor pressure of the complex was calculated using an improved COSMO-SAC method.

TABLE 19

| | |
|---|---|
| Polarizability volume | 377.80 |
| Relative dielectric constant | 2.2 |
| Surface charge density | The area having a surface |
| | charge density of 0.007 e/Å² |
| | or more is 0.2% with respect |
| | to the entire molecular area. |
| | The area having a surface |
| | charge density of 0.007 e/Å² |
| | or less is 0.2% with respect |
| | to the entire molecular area. |
| Vapor pressure at 100 °C | 0.01 Torr |

### Comparative Example 11

### Ru(iPr-AMD)3

For the above-described complex, the polarizability volume, relative dielectric constant, and surface charge density of the complex were calculated using the DFT method, and the vapor pressure of the complex was calculated using an improved COSMO-SAC method.

TABLE 20

| | |
|---|---|
| Polarizability volume | 403.0 |
| Relative dielectric constant | 2.32 |
| Surface charge density | The area having a surface |
| | charge density of 0.007 e/Å² |
| | or more is 0.3% with respect |
| | to the entire molecular area. |
| | The area having a surface |
| | charge density of 0.007 e/Å² |
| | or less is 0.5% with respect |
| | to the entire molecular area. |
| Vapor pressure at 100 °C | 0.003 Torr |

### Comparative Example 12

### W(iPr-AMD)3

For the above-described complex, the polarizability volume, relative dielectric constant, and surface charge density of the complex were calculated using the DFT method, and the vapor pressure of the complex was calculated using an improved COSMO-SAC method.

TABLE 21

| | |
|---|---|
| Polarizability volume | 379.8 |
| Relative dielectric constant | 2.23 |
| Surface charge density | The area having a surface |
| | charge density of 0.007 e/Å² |
| | or more is 0% with respect to |
| | the entire molecular area. |
| | The area having a surface |
| | charge density of 0.007 e/Å² |
| | or less is 0.5% with respect |
| | to the entire molecular area. |
| Vapor pressure at 100 °C | 0.01 Torr |

### INDUSTRIAL APPLICABILITY

According to the complex disclosed herein, ALD enables a high-purity thin film to be efficiently deposited. Therefore, the complex and the atomic layer deposition of the present disclosure are suitably used for a variety of applications, such as manufacturing of semiconductor substrates.

The present disclosure includes the following embodiments.

### [Item 1]

A raw material complex for forming a thin metal film, having a central metal and a ligand coordinated to the central metal,
wherein the central metal has an atomic polarizability of 45 to 51 and the complex satisfies the following conditions:
a polarizability volume≤200 and
a relative dielectric constant≤2.20.

### [Item 2]

A raw material complex for forming a thin metal film, having a central metal and a ligand coordinated to the central metal,
wherein the central metal has an atomic polarizability of 52 to 90 and the complex satisfies the following conditions:
a polarizability volume≤240 and
a relative dielectric constant≤2.50.

### [Item 3]

The raw material complex for forming a thin metal film according to item 1 or 2, satisfying that an area having a surface charge density of 0.007 e/Å² or more is 10% or less with respect to an entire complex molecular area, or an area having a surface charge density of −0.007 e/Å² or less is 10% or less with respect to an entire complex molecular area.

### [Item 4]

The raw material complex for forming a thin metal film according to any one of items 1 to 3, wherein the ligand is a monodentate ligand, a polydentate ligand, or both thereof.

### [Item 5]

The raw material complex for forming a thin metal film according to any one of items 1 to 4, wherein an atom that coordinates with a metal in the ligand has a Pauling electronegativity of 3.1 or less.

### [Item 6]

The raw material complex for forming a thin metal film according to any one of items 1 to 5, wherein the ligand has at least one branched alkyl group having three or more carbon atoms.

### [Item 7]

The raw material complex for forming a thin metal film according to any one of items 4 to 6, wherein the monodentate ligand is carbonyl, alkyne, alkyl, fluoroalkyl, allyl, aminoalkyl, hydride, or alkylsilane.

### [Item 8]

The raw material complex for forming a thin metal film according to any one of items 4 to 6, wherein the polydentate ligand is a bidentate ligand, and the bidentate ligand is alkyldiene, cyclopentadiene, acetylacetonate, alkyldiamine, or alkyldisilane.

### [Item 9]

The raw material complex for forming a thin metal film according to any one of items 4 to 6, wherein the polydentate ligand is a tridentate ligand, and the tridentate ligand is amidinate.

### [Item 10]

The raw material complex for forming a thin metal film according to any one of items 1 to 9, wherein the central metal has an oxidation number of 1 or greater.

### [Item 11]

The raw material complex for forming a thin metal film according to any one of items 1 and 3 to 10, wherein the central metal is cobalt, nickel, or copper.

### [Item 12]

The complex for forming a thin metal film according to any one of items 1 and 3 to 11, having a vapor pressure at 100° C. of 6.0 Torr or more.

### [Item 13]

The complex for forming a thin metal film according to any one of items 1 and 3 to 12, wherein the central metal is cobalt and the complex has a vapor pressure at 100° C. of 6.0 Torr or more.

### [Item 14]

The complex for forming a thin metal film according to any one of items 1 and 3 to 13, wherein the central metal is nickel and the complex has a vapor pressure at 100° C. of 6.3 Torr or more.

### [Item 15]

The complex for forming a thin metal film according to any one of items 1 and 3 to 14, wherein the central metal is copper and the complex has a vapor pressure at 100° C. of 6.7 Torr or more.

### [Item 16]

The raw material complex for forming a thin metal film according to any one of item 2 to 10, wherein the central metal is molybdenum, ruthenium, or tungsten.

### [Item 17]

The complex for forming a thin metal film according to any one of items 2 to 10 and 16, having a vapor pressure at 100° C. of 0.6 Torr or more.

### [Item 18]

The complex for forming a thin metal film according to any one of items 2 to 10, 16 and 17, wherein the central metal is molybdenum and the complex has a vapor pressure at 100° C. of 0.6 Torr or more.

### [Item 19]

The complex for forming a thin metal film according to any one of items 2 to 10 and 16 to 18, wherein the central metal is ruthenium and the complex has a vapor pressure at 100° C. of 2.8 Torr or more.

### [Item 20]

The complex for forming a thin metal film according to any one of items 2 to 10 and 16 to 19, wherein the central metal is tungsten and the complex has a vapor pressure at 100° C. of 3.6 Torr or more.

### [Item 21]

The complex for forming a thin metal film according to any one of items 1 to 20, for use in an atomic layer deposition.

### [Item 22]

An atomic layer deposition, using the complex according to any one of items 1 to 21 as a raw material compound.

### [Item 23]

The atomic layer deposition according to item 22, wherein a film deposition temperature upon film deposition using the complex according to any one of items 1 to 21 is 200° C. or lower.

### [Item 24]

The atomic layer deposition according to item 22 or 23 for use in production of semiconductor substrates.

### [Item 25]

A method for selecting a raw material complex for use in an atomic layer deposition, comprising selecting the raw material complex which has
a central metal having an atomic polarizability of 45 to 51,
a polarizability volume of 200 or less,
a relative dielectric constant of 2.20 or less, and
a surface charge density such that an area having a surface charge density of 0.007 e/Å² or more is 10% or less with respect to an entire molecular area, or an area having a surface charge density of −0.007 e/Å² or less is 10% or less with respect to an entire molecular area.

### [Item 26]

A method for selecting a raw material complex for use in an atomic layer deposition, comprising selecting the raw material complex which has
a central metal having an atomic polarizability of 52 to 90,
a polarizability volume of 220 or less,
a relative dielectric constant of 2.50 or less, and
a surface charge density such that an area having a surface charge density of 0.007 e/Å² or more is 10% or less with respect to an entire molecular area, or an area having a surface charge density of −0.007 e/Å² or less is 10% or less with respect to an entire molecular area.

### [Item 27]

The method according to item 25, wherein the complex has a vapor pressure at 100° C. of 1.0 Torr or more.

### [Item 28]

The method according to item 25 or 27, wherein the central metal of the complex is cobalt, nickel, or copper.

### [Item 29]

The method according to claim 26, wherein the complex has a vapor pressure at 100° C. of 0.6 Torr or more.

### [Item 30]

The method according to item 26 or 29, wherein the central metal of the complex is molybdenum, ruthenium, or tungsten.

### [Item 31]

The method according to any one of items 25 to 30, wherein the polarizability volume, the relative dielectric constant, the surface charge density, and the vapor pressure of the complex are determined by simulation.

### [Item 32]

The method according to item 31, wherein the simulation is at least one of a COSMO-SAC method, a DFT method, and an AMS method.

### [Item 33]

The method according to item 32, wherein the COSMO-SAC method used in the simulation is a modified COSMO-SAC method.

### REFERENCE SIGNS LIST

1 film deposition chamber
2 raw material container
3, 9, 12, 17, 20 mass flow controller
4 needle valve
5, 13 supply line
6, 14 exhaust line
7, 8, 10, 11, 15, 16, 18, 19 valves
21 film deposition stage
22 discharge line
23 butterfly valve
24 pump
25 liquid raw material
26, 27 pressure gauge

1. A raw material complex for forming a thin metal film, having a central metal and a ligand coordinated to the central metal,
wherein the central metal has an atomic polarizability of 45 to 51 and the complex satisfies the following conditions:
a polarizability volume≤200 and
a relative dielectric constant≤2.20.

2. A raw material complex for forming a thin metal film, having a central metal and a ligand coordinated to the central metal,
wherein the central metal has an atomic polarizability of 52 to 90 0 and the complex satisfies the following conditions:
a polarizability volume≤240 and
a relative dielectric constant≤2.50.

3. The raw material complex for forming a thin metal film according to claim 1, satisfying that an area having a surface charge density of 0.007 e/Å² or more is 10% or less with respect to an entire complex molecular area, or an area having a surface charge density of −0.007 e/Å² or less is 10% or less with respect to an entire complex molecular area.

4. The raw material complex for forming a thin metal film according to claim 1, wherein the ligand is a monodentate ligand, a polydentate ligand, or both thereof.

5. The raw material complex for forming a thin metal film according to claim 1, wherein an atom that coordinates with a metal in the ligand has a Pauling electronegativity of 3.1 or less.

6. The raw material complex for forming a thin metal film according to claim 1, wherein the ligand has at least one branched alkyl group having three or more carbon atoms.

7. The raw material complex for forming a thin metal film according to claim 4, wherein the monodentate ligand is carbonyl, alkyne, alkyl, fluoroalkyl, allyl, aminoalkyl, hydride, or alkylsilane.

8. The raw material complex for forming a thin metal film according to claim 4, wherein the polydentate ligand is a bidentate ligand, and the bidentate ligand is alkyldiene, cyclopentadiene, acetylacetonate, alkyldiamine, or alkyldisilane.

9. The raw material complex for forming a thin metal film according to claim 4, wherein the polydentate ligand is a tridentate ligand, and the tridentate ligand is amidinate.

10. The raw material complex for forming a thin metal film according to claim 1, wherein the central metal has an oxidation number of 1 or greater.

11. The raw material complex for forming a thin metal film according to claim 1, wherein the central metal is cobalt, nickel, or copper.

12. The complex for forming a thin metal film according to claim 1, having a vapor pressure at 100° C. of 6.0 Torr or more.

13. The complex for forming a thin metal film according to claim 1, wherein the central metal is cobalt and the complex has a vapor pressure at 100° C. of 6.0 Torr or more.

14. The complex for forming a thin metal film according to claim 1, wherein the central metal is nickel and the complex has a vapor pressure at 100° C. of 6.3 Torr or more.

15. The complex for forming a thin metal film according to claim 1, wherein the central metal is copper and the complex has a vapor pressure at 100° C. of 6.7 Torr or more.

16. The raw material complex for forming a thin metal film according to claim 2, wherein the central metal is molybdenum, ruthenium, or tungsten.

17. The complex for forming a thin metal film according to claim 2, having a vapor pressure at 100° C. of 0.6 Torr or more.

18. The complex for forming a thin metal film according to claim 2, wherein the central metal is molybdenum and the complex has a vapor pressure at 100° C. of 0.6 Torr or more.

19. The complex for forming a thin metal film according to claim 2, wherein the central metal is ruthenium and the complex has a vapor pressure at 100° C. of 2.8 Torr or more.

20. The complex for forming a thin metal film according to claim 2, wherein the central metal is tungsten and the complex has a vapor pressure at 100° C. of 3.6 Torr or more.

21. The complex for forming a thin metal film according to claim 1 for use in an atomic layer deposition.

22. The complex for forming a thin metal film according to claim 2 for use in an atomic layer deposition.

23. An atomic layer deposition, using the complex according to claim 1 as a raw material compound.

24. An atomic layer deposition, using the complex according to claim 2 as a raw material compound.

25. The atomic layer deposition according to claim 23, wherein a film deposition temperature upon film deposition using the complex is 200° C. or lower.

26. The atomic layer deposition according to claim 24, wherein a film deposition temperature upon film deposition using the complex is 200° C. or lower.

27. The atomic layer deposition according to claim 23 for use in production of semiconductor substrates.

28. The atomic layer deposition according to claim 24 for use in production of semiconductor substrates.
